(19) United States
(12) Patent Application Publication
(10) Pub. No.: US 2005/0260502 A1
(43) Pub. Date: Nov. 24, 2005

(54) Method and mask for forming a photo-induced pattern

(76) Inventor: Moitreyee Mukherjee-Roy, Parisian (SG)

Correspondence Address: CHRISTIE, PARKER & HALE, LLP, PO BOX 7068, PASADENA, CA, 91109-7068, US

(21) Appl. No.: 10/847,899

(22) Filed: May 18, 2004

(51) Int. Cl. G03F 9/00; G03C 5/00

(52) U.S. Cl. 430/5; 430/322; 430/323; 430/324

(57) ABSTRACT

A lithographic mask comprising a primary pattern having a substantially continuously changing critical dimension in at least a first portion thereof, and a resolution enhancement feature in proximity to an edge of the primary pattern in the first portion.

### FIELD OF INVENTION

The present invention relates broadly to a method and mask for forming a photo-induced pattern having at least one continuously changing critical dimension in at least a portion of the pattern, and to a method of shaping a waveguide in a photosensitive material.

### BACKGROUND

The continuous reduction in size in the geometry in e.g. semiconductor devices drives the development and implementation of resolution enhancement techniques.

Lithography is one of the techniques used for forming photo-induced patterns on substrates in the manufacturing of e.g. semiconductor devices.

To date, solutions have been proposed for high-resolution enhancement lithography for conventional semiconductor processing. Significantly the features in conventional semiconductor processing typically comprise lines, constant-width trenches with or without sloping sidewalls, or holes.

At the same time, there is now a growing demand to provide high-resolution enhancement lithography for patterns having continuously changing critical dimensions, e.g. patterning of optical waveguides.

There is therefore a need to provide high-resolution enhancement techniques that may facilitate formation of patterned photo-induced structures with continuously changing critical dimensions.

### SUMMARY

In accordance with a first aspect of the present invention there is provided a lithographic mask comprising a primary pattern having a substantially continuously changing critical dimension in at least a first portion thereof, and a resolution enhancement feature in proximity to an edge of the primary pattern in the first portion thereof.

The resolution enhancement feature may comprise an assist feature in proximity to the edge of the primary pattern in the first portion.

The assist feature may comprise one or more scatter bars. The scatter bars may have the same or a different phase as the primary pattern. The scatter bars may have the same or different transmission as the primary pattern. The one or more scatter bars may have the same or different dimensions with respect to each other. The scatter bars may have constant cross-sections or changing cross-sections throughout their respective lengths.

The resolution enhancement feature may comprise a transmission region adjacent the edge of the primary pattern in the first portion and having a substantially 180° phase shift compared to the primary pattern.

The first portion of the primary pattern may comprises a tip, and the resolution enhancement feature may comprise a transmission region adjacent one side of the tip and having a substantially 180° phase shift compared to the primary pattern, wherein a substantially straight edge of the transmission region extends beyond the tip along a central axis of the tip.

In accordance with a second aspect of the present invention there is provided a method of forming a photo-induced pattern having at least one substantially continuously changing critical dimension in at least a portion thereof, the method comprising the steps of utilising a primary lithographic pattern having a substantially continuously changing critical dimension in at least a first portion thereof, and simultaneously utilising a resolution enhancement feature in proximity to an edge of the primary pattern in the first portion thereof in transferring the primary lithographic pattern.

The resolution enhancement feature may comprise an assist feature in proximity to the edge of the primary pattern in the first portion.

The assist feature may comprise one or more scatter bars. The scatter bars may have the same or a different phase as the primary pattern. The scatter bars may have the same or different transmission as the primary pattern. The one or more scatter bars may have the same or different dimensions with respect to each other. The scatter bars may have constant cross-sections or changing cross-sections throughout their respective lengths.

The resolution enhancement feature may comprise a transmission region adjacent the edge of the primary pattern in the first portion and having a substantially 180° phase shift compared to the primary pattern.

The first portion of the primary pattern may comprise a tip, and the resolution enhancement feature may comprise a transmission region adjacent one side of the tip and having a substantially 180° phase shift compared to the primary pattern, wherein a substantially straight edge of the transmission region extends beyond the tip along a central axis of the tip.

The photo-induced pattern may comprise an optical waveguide pattern.

In accordance with a third aspect of the present invention there is provided a method of shaping a waveguide in a photosensitive material, the waveguide having at least one substantially continuously changing critical dimension in at least a portion thereof, the method comprising the steps of utilising a primary lithographic pattern having a substantially continuously changing critical dimension in at least a first portion thereof, and simultaneously utilising a resolution enhancement feature in proximity to an edge of the primary pattern in the first portion thereof in transferring the primary lithographic pattern.

### BRIEF DESCRIPTION OF THE DRAWINGS

Embodiments of the invention will be better understood and readily apparent to one of ordinary skill in the art from the following written description, by way of example only and in conjunction with the drawings, in which:

FIG. 1 is a schematic top view of a mask in accordance with an embodiment of the present invention.

FIG. 2 is a schematic side view of the mask of FIG. 1 and image forming, according to an embodiment of the present invention.

FIG. 3 is a schematic top view of another mask in accordance with an embodiment of the present invention.

FIG. 4 is a schematic top view of another mask in accordance with an embodiment of the present invention.

FIG. 5 shows a scanning electronic microscopy (SEM) image of a 100 nm tip formed without an assist feature.

FIG. 6 shows a scanning electronic microscopy (SEM) image of a 100 nm tip formed according to an embodiment.

### DETAILED DESCRIPTION

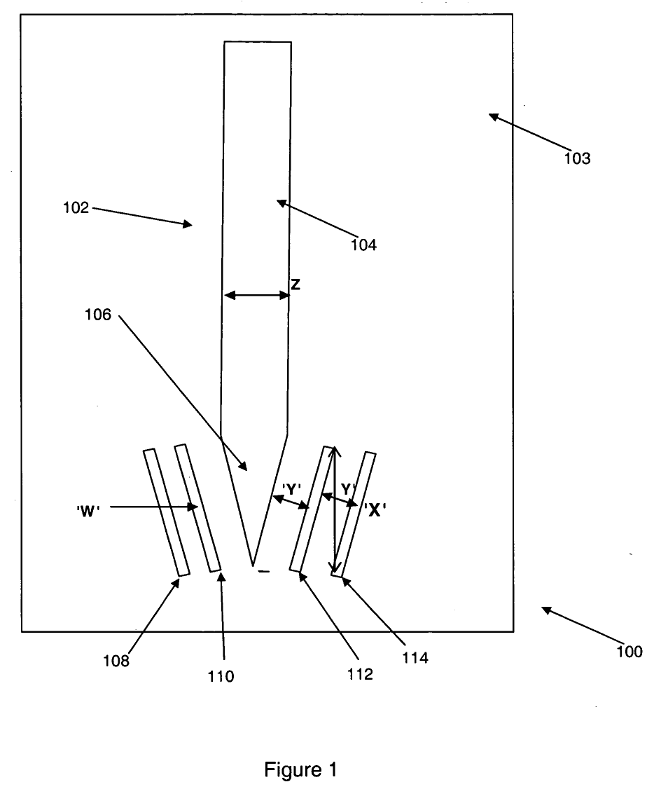

FIG. 1 is a schematic top view of a mask 100 for resolution enhanced lithography in an embodiment of the present invention. The mask 100 comprises a primary feature 102 of chrome deposited on the main body 103 of the mask 100. The main body 103 is made from quartz in the example embodiment.

The primary feature 102 comprises a waveguide portion 104, and a waveguide tip portion 106. Assist features in the form of chrome deposited scatter bars 108, 110, 112 and 114 respectively are provided adjacent the waveguide tip region 106, to enhance the resolution in the imaging of the mask 100 onto a photo-resist surface coated onto e.g. a silicon substrate (not shown).

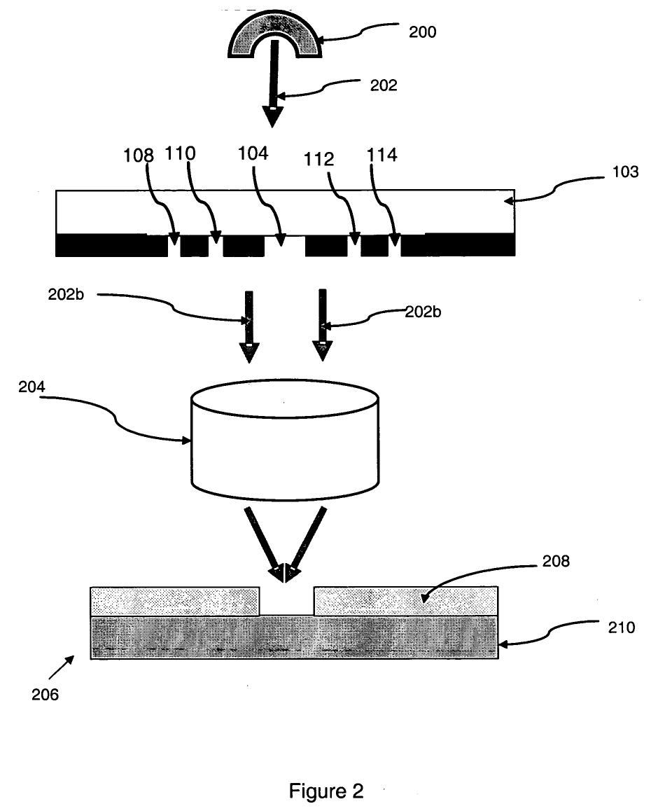

FIG. 2 is a schematic cross sectional view illustrating the mask 100 and image formation in an example embodiment. In FIG. 2, light from a light source 200 is directed towards the mask 100, with arrow 202 indicating the light wave front.

Beyond the mask 100, the light 202b is passed through a lens 204 and a final image of the desired structure is formed at the plane of the silicon substrate 206, more particularly at a positive photo-resist surface 208 coated onto a silicon wafer 210.

It is noted here that at the plane of the substrate 206 only the primary feature 102 will be printed, while the scatter bars 108, 110, 112 and 114 provide improvement to the image quality of the waveguide tip 106 (see FIG. 1). The scatter bars 108, 110, 112 and 114 function as assist features forming an optical proximity correction pattern, which provides a substantially similar transfer pattern of the primary feature 102 after it is transferred. It will be appreciated by a person skilled in the art that the dimensions of the scatter bars 108, 110, 112 and 114 are therefore chosen to be sub-resolution, and will depend on the wavelength of the illuminating light 202.

The inventors have recognized that assist features for providing optical proximity correction patterns in resolution enhanced lithography can be utilized in transfer of patterns which have continuously changing critical dimensions, such as the waveguide tip 106 (see FIG. 1) in the example embodiment. Previously, assist features have only been used to provide an optical proximity correction pattern providing a substantially similar transfer pattern of features having no continuously changing critical dimensions such as lines, trenches, or dots. Reference is made to U.S. Pat. No. 6,165,693, assigned to United Microelectronics Corp, as an example of the design of assist feature for primary patterns having no continuously changing critical dimensions.

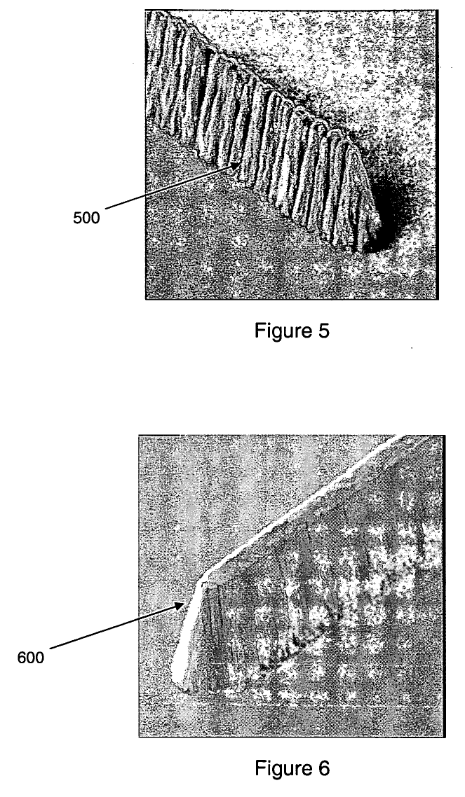

FIGS. 5 and 6 show scanning electronic microscopy (SEM) images of 100 nm tips formed without and with assist features respectively. In FIG. 5, the tip 500 has very rough edges which appear “chewed up” or discontinuous, indicative of a low depth of focus (DOF) in the imaging during the photo-lithography process.

In contrast, in FIG. 6 the tip 600 has more clearly defined edges, and generally less roughness of the edges and the sidewalls, indicative of an improved DOF.

With reference to FIG. 1, tip 600 (FIG. 6) was formed utilizing a distance of about 200 nm between the tip portion 106 and the scatter bars 110, 112 respectively, a distance of 200 nm between the adjacent scatter bars 108, 110, 112 and 114. Each of the scatter bars 108, 110, 112 and 114 had a width of 80 nm.

The parameters to optimize the resultant tip structure with the example embodiment shown in FIG. 1 include: Distance of first assist feature from the tapered primary feature; distance of second assist feature from tapered primary feature (and first assist feature); width of the assist feature; assist feature angle with respect to tip angle (may be different than taper angle of primary structure).

In the example embodiment, the scatter bars 108, 110, 112, and 114 have the same phase and transmission characteristics as the tip portion 106 of the primary feature 102. However, it will be appreciated that in different embodiments, scatters bars having a different phase and/or different transmission compared to the primary feature 102 may be utilized. Furthermore, it will be appreciated that in different embodiments, scatter bars of changing cross-sections along their respective lengths may be used. Furthermore, the scatter bars may have different dimensions with respect to each other.

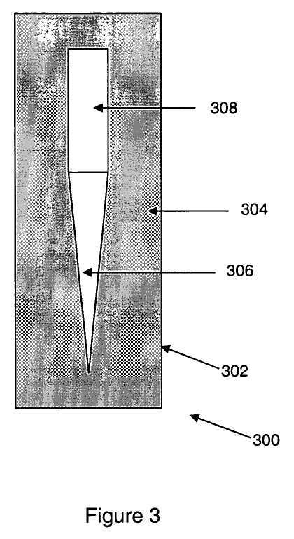

FIG. 3 is a schematic top view of an attenuated phase shift mask (PSM) 300 for resolution enhanced lithography in another embodiment of the present invention.

The mask 300 comprises a quartz main body 302 on which is formed a background region 304 having a transmission of about 4 to 20%, and with a 180° phase. In the example embodiment, the background region is formed through deposition of a suitable material, e.g. molybdenum silicite, of a chosen thickness onto the quartz main body 302.

The mask 300 further comprises a foreground “tip” region 306 for formation of a waveguide tip, and a foreground “waveguide” region 308 for formation of a waveguide portion of the waveguide tip. In the foreground regions 306 and 308, 100% transmission is provided, with 0° phase, i.e. the quartz main body 302 is exposed in the foreground regions.

It will be appreciated by a person skilled in the art that the mask 300 functions as an attenuated PSM design for patterning a negative resist or for damascene patterning.

The inventors have recognized that PSM can be used for providing resolution enhancement lithography for patterns which have continuously changing critical dimensions, such as a waveguide tip. Previously, PSMs have only been used to provide resolution-enhanced lithography of features having no continuously changing critical dimensions such as lines, trenches, or dots. Reference is made to “Novel Strong Resolution Enhancement Technology with Phase-Shifting Mask for Logic Date Pattern Fabrication”, Takahiro Matsuo et. al. Optical Microlithography XVI, Proc. SPIE, Vol. 5040, pp 383, as an example of the application of PSM for resolution enhanced lithography of patterns having no continuously changing critical dimensions.

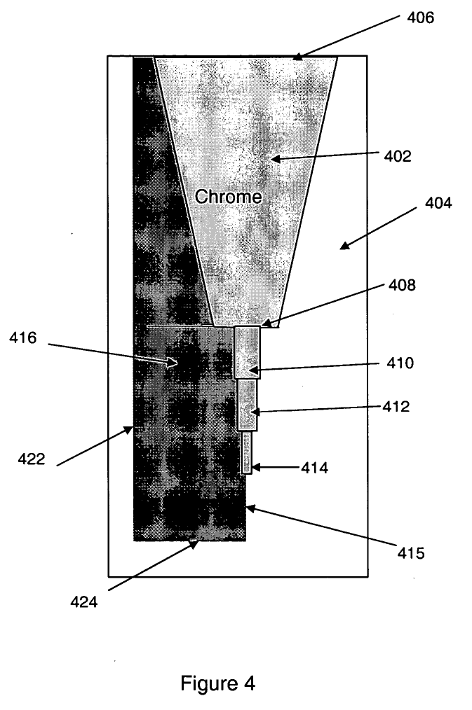

Another embodiment of the present invention will now be described with reference to FIG. 4.

FIG. 4 shows a first mask 400 for use in the example embodiment. The mask 400 comprises a main chrome pad 402 on a quartz main body 404 of the mask 400. The pattern 402 is tapered from a wide end 406 down to a narrow end 408 of about 200 nm. Three further chrome pads 410, 412, 414 respectively are provided in a stacked arrangement adjacent the narrow end 408 of the main pad 402. The pads 410, 412, 414 are of decreasing widths with the smallest pad 414 having a cross section of about 150 nm.

A transparent pad 416 having 180° phase shift is also provided. The pad 416 is formed adjacent the edges of the pads 410, 412, 414, with a straight edge 415 of the pad 416 extending beyond the smallest pad 414. The pad 416, in example embodiment, comprises of an area of the quartz main body 404, on which a suitable material, e.g. molybdenum silicite, of a chosen thickness has been deposited. The transmission in the area of the pad 416 may be in the range from about 6 to about 100%. The quartz main body 404 has a clear background at 0 phase.

It will be appreciated by a person skilled in the art that in the image formation utilizing the mask 400, a “phase edge plus chrome border” technique is utilized in the taper region from about 200 nm to about 150 nm in the example embodiment, and a “phase edge” technique only in the very tip of the tapered pattern.

It will also be appreciated by a person skilled in the art, that after a first exposure step utilizing the mask 400, additional, unwanted phase edges in a positive resist layer, corresponding to the edges of the pad 416, e.g. 422, 424, can be removed utilizing a mask with an appropriate binary pad arrangement to protect the desired pattern.

In the foregoing manner, a lithography mask and a method of forming a photo-induced pattern and a method of shaping a waveguide in a photosensitive material are disclosed. Only several embodiments are described. However, it will be apparent to one skilled in the art in view of this disclosure that numerous changes and/or modifications may be made without departing from the scope of the invention.

For example, it will be appreciated that depending on whether a positive or negative resist material is utilized, either bright field or dark field mask design may be applied in different embodiments of the present invention. Furthermore, the values of the background and foreground transmissions in attenuated PSM design embodiments of the present invention can vary according to specific requirements, and/or specific mask manufacturing methods.

Furthermore, it will be appreciated that in different embodiments, features of the masks described with reference to the example embodiments may be combined to further enhance the resolution achievable. For example, assist features may be provided in the examples described with reference to FIGS. 3 and 4.

1. A lithographic mask comprising:
a primary pattern having a substantially continuously changing critical dimension in at least a first portion thereof, and
a resolution enhancement feature in proximity to an edge of the primary pattern in the first portion thereof.

2. The mask as claimed in claim 1, wherein the resolution enhancement feature comprises an assist feature in proximity to the edge of the primary pattern in the first portion.

3. The mask as claimed in claim 2, wherein the assist feature comprises one or more scatter bars.

4. The mask as claimed in claim 3, wherein the scatter bars have the same or a different phase as the primary pattern.

5. The mask in claims 3 or 4, wherein the scatter bars have the same or different dimensions with respect to each other.

6. The mask claimed in claim 3, wherein the scatter bars have constant cross-sections or changing cross-sections throughout their respective lengths.

7. The mask as claimed in claim 1, wherein the resolution enhancement feature comprises a transmission region adjacent the edge of the primary pattern in the first portion and having a substantially 180° phase shift compared to the primary pattern.

8. The mask as claimed in claim 1, wherein the first portion of the primary pattern comprises a tip, and the resolution enhancement feature comprises a transmission region adjacent one side of the tip and having a substantially 180° phase shift compared to the primary pattern, wherein a substantially straight edge of the transmission region extends beyond the tip along a central axis of the tip.

9. A method of forming a photo-induced pattern having at least one substantially continuously changing critical dimension in at least a portion thereof, the method comprising the steps of
utilising a primary lithographic pattern having a substantially continuously changing critical dimension in at least a first portion thereof, and
simultaneously utilising a resolution enhancement feature in proximity to an edge of the primary pattern in the first portion thereof in transferring the primary lithographic pattern.

10. The method as claimed in claim 9, wherein the resolution enhancement feature comprises an assist feature in proximity to the edge of the primary pattern in the first portion.

11. The method as claimed in claim 10, wherein the assist feature comprises one or more scatter bars.

12. The mask as claimed in claim 11, wherein the scatter bars have the same or a different phase as the primary pattern.

13. The mask in claims 11 or 12, wherein the scatter bars have the same or different dimensions with respect to each other.

14. The mask claimed in claim 11, wherein the scatter bars have constant cross-sections or changing cross-sections throughout their respective lengths.

15. The method as claimed in claim 9, wherein the resolution enhancement feature comprises a transmission region adjacent the edge of the primary pattern in the first portion and having a substantially 180° phase shift compared to the primary pattern.

16. The method as claimed claim 9, wherein the first portion of the primary pattern comprises a tip, and the resolution enhancement feature comprises a transmission region adjacent one side of the tip and having a substantially 180° phase shift compared to the primary pattern, wherein a substantially straight edge of the transmission region extends beyond the tip along a central axis of the tip.

17. The method as claimed in claim 9, wherein the photo-induced pattern comprises an optical waveguide pattern.

18. A method of shaping a waveguide in a photosensitive material, the waveguide having at least one substantially continuously changing critical dimension in at least a portion thereof, the method comprising the steps of
utilising a primary lithographic pattern having a substantially continuously changing critical dimension in at least a first portion thereof, and
simultaneously utilising a resolution enhancement feature in proximity to an edge of the primary pattern in the first portion thereof in transferring the primary lithographic pattern.
